(19) United States
(12) Patent Application Publication
(10) Pub. No.: US 2024/0170383 A1
(43) Pub. Date: May 23, 2024

(54) ELECTRONIC DEVICE INCLUDING A DIE ARRANGED BETWEEN FIRST AND SECOND SUBSTRATES

(71) Applicant: Microchip Technology Caldicot Limited, Caldicot Monmouthshire (GB)

(72) Inventors: George Taylor, Wales (GB); Piers Tremiett, Coleford (GB)

(73) Assignee: Microchip Technology Caldicot Limited, Caldicot Monmouthshire (GB)

(21) Appl. No.: 18/217,800

(22) Filed: Jul. 3, 2023

Related U.S. Application Data
(60) Provisional application No. 63/427,065, filed on Nov. 21, 2022.

(51) Int. Cl. H01L 23/498; H01L 23/367; H01L 25/16

(52) U.S. Cl. CPC H01L 23/49827; H01L 23/367; H01L 23/49811; H01L 25/16; H01L 24/32; H01L 2224/32225

(57) ABSTRACT

An electronic device includes a die mounted between a first substrate and a second substrate. The first substrate includes a first substrate die contact on a first side of the first substrate, and a first substrate terminal contact on a second side of the first substrate opposite the first side, the first substrate terminal contact electrically and thermally connected to the first substrate die contact. The second substrate includes a second substrate die contact on a first side of the second substrate, and a second substrate terminal contact on a second side of the second substrate opposite the first side, the second substrate terminal contact electrically and thermally connected to the second substrate die contact. The die includes a first die element conductively connected to the first substrate die contact, and a second die element conductively connected to the second substrate die contact.

### RELATED PATENT APPLICATION

This application claims priority to commonly owned U.S. Provisional Patent Application No. 63/427,065 filed Nov. 21, 2022, the entire contents of which are hereby incorporated by reference for all purposes.

### TECHNICAL FIELD

The present disclosure relates to electronic devices, and more particularly to an electronic device (e.g., a power module) including a die arranged between first and second substrates.

### BACKGROUND

Conventional electronic devices including heat-generating electronics (e.g., dies), for example power modules (or “power packages”) including one or more metal-oxide-semiconductor field-effect transistor (power MOSFET), typically rely on using ceramic substrates, or other isolation layers, to provide electrical separation between the heat-generating electronics and a heatsink. In certain conventional devices, to avoid physical interference with such thermal management structures, busbars for providing electrical connection to the respective electronics in the device are often located spaced apart from such electronics, and electrically connected to the electronics by copper tracks or traces, wire bonds, leadframe leads, or other conductive connections. However, locating the busbar connections away from the electronics typically creates an inherent performance bottleneck (due to high inductance/losses). This bottleneck results from the complex electrical paths needed to transmit signals to and from the device. For example, some conventional electronic devices include power MOSFETs mounted on a ceramic substrate that electrically isolates them from a heatsink in a vertical plane. The power MOSFETs are electrically connected through the use of wire bonds, ribbon bonds, clips, substrate tracks/traces, spacers, multiple soldered connection, and/or power terminal busbars/leadframes. The power signals travel along copper traces on a first side (typically the top side) of a substrate before connecting to dedicated power terminals enabling connection to an external busbar or cable. Accordingly, conventional devices provide electrical performance at the expense of thermal performance, and vice versa.

In addition, conventional electronic devices (e.g., power modules) that include wire bond connections between the substrate and electronics may be subject to failure at the wire bond connections, for example in power modules subjected to harsh cycling requirements, for example in motor control and power generation applications.

Other conventional electronic devices (e.g., power modules) use other electrical isolation layers (i.e., other than ceramics), or layers added between the heat-generating electronics and heatsink(s). For example, some devices include silicone fiberglass pads for electrical isolation. However, regardless of the materials or structures provided for electrical isolation, conventional devices (e.g., power modules) typically rely on dedicated terminals/connections for high power connections between the electronics and the relevant supply and load, which may sacrifice current flow in exchange for thermal management.

There is a need for improved electronic devices (e.g., power modules), for example providing efficient heat transfer and communication of electrical signals between included electronics (e.g., power dies) and external electronics (e.g., power supply and/or load).

### SUMMARY

As disclosed herein, an electronic device (e.g., a power module) may include at least one die mounted or “sandwiched” between first and second substrates including respective conductive structures, which arrangement may provide improved electrical and heat flow through the electronic device, e.g., as compared with certain conventional power modules. The respective substrates (between which the die(s) are mounted) may include electrically and thermally conductive structures facilitating heat transfer from away the die(s) and communication of electrical signals to and/or from the die(s). In some examples, by mounting die(s) between a pair of substrates that provide both electrical contact and heat transfer, various structures of conventional power modules may be omitted or eliminated, e.g., certain wire bonds, additional traces, or dedicated power terminals or leadframes provided in certain conventional devices. As a result, some examples may provide a power module exhibiting a low loop inductance as compared with certain conventional devices.

An electronic device according to some examples may include multi-layer substrates (e.g., multi-layer PCB's) including electrically conductive structures (e.g., metal coins, inlays and/or vias) to transfer heat and conduct electrical signals to outer layers or outer structures of the device. For example, heat and electrical signals may be transferred from heat-generating die(s) to respective heatsinks using an appropriate electrically conductive thermal interface layer. In some examples, a dielectric layer is formed on respective outer surfaces of respective heatsinks, which dielectric layer coated heatsinks may be cooled by a fluid-based cooling system.

An electronic device as disclosed herein may include any type or types of die(s) mounted between a pair of substrates, for example at least one an insulated-gate bipolar transistor (IGBT), a thyristor, or vertical MOSFET. Some examples provide a power module including at least one power die (e.g., power MOSFET) mounted between a pair of substrates (e.g., multi-layer substrates) that provide electrical connection to the at least one power die and facilitate heat transfer away from the at least one power die. In some examples, gate drivers may be mounted on the respective substrates and connected directly to respective gates of the respective power dies.

In some examples, electronic devices as disclosed herein (i.e., including at least one die mounted between a pair of substrates) can be arranged in various circuitry topologies, for example a half bridge topology, an H-Bridge topology, a single-phase inverter topology, a three-phase inverter topology, a neutral point clamped (NPC) topology, a mixed voltage NPC (MNPC), or an active NPC (ANPC) topology, without limitation.

Example electrical devices (e.g., power modules) as disclosed herein may be used in various applications, for example for electrification, transportation (e.g., electric vehicles (EVs), EV charging, boats, aircraft, or trains, without limitation), and power infrastructure (e.g., power grid management, or energy generation, without limitation), without limitation.

One aspect provides an electronic device including a die mounted between a first substrate and a second substrate. The die includes a first die element at a first side of the die, and a second die element at a second side of the die opposite the first side of the die. The first substrate includes a first substrate die contact on a first side of the first substrate, the first substrate die contact electrically and thermally connected to the first die element, and a first substrate terminal contact on a second side of the first substrate opposite the first side of the first substrate, the first substrate terminal contact electrically and thermally connected to the first substrate die contact. The second substrate includes a second substrate die contact on a first side of the second substrate, the second substrate die contact electrically and thermally connected to the second die element, and a second substrate terminal contact on a second side of the second substrate opposite the first side of the second substrate, the second substrate terminal contact electrically and thermally connected to the second substrate die contact.

In some examples, the first substrate, the die, and the second substrate collectively define a conductive path allowing a communication of current from the first substrate terminal contact to the second substrate terminal contact through the first substrate, the die, and the second substrate, during at least one operational mode of the die.

In some examples, the electronic device includes a first substrate integrated conductive structure extending through a thickness of the first substrate to electrically and thermally connect the first substrate die contact with the first substrate terminal contact, and a second substrate integrated conductive structure extending through a thickness of the second substrate to electrically and thermally connect the second substrate die contact with the second substrate terminal contact.

In some examples, the first substrate comprises a first printed circuit board, and the second substrate comprises a second printed circuit board.

In some examples, the die comprises a vertical transistor, the first die element comprises a source of the vertical transistor, the second die element comprises a drain of the vertical transistor, the first substrate die contact on the first side of the first substrate comprises a source contact, and the second substrate die contact on the first side of the second substrate comprises a drain contact.

In some examples, the die comprises a gate terminal of the vertical transistor, the first substrate comprises a gate contact on the first side of the first substrate, and the electronic device comprises a gate driver mounted on the first substrate and connected to the gate contact.

In some examples, the electronic device includes gate driver control circuitry mounted on the first substrate and connected to the gate driver.

In some examples, the electronic device includes a first busbar electrically and thermally connected to the first substrate terminal contact, and a second busbar electrically and thermally connected to the second substrate terminal contact.

In some examples, the electronic device includes a power supply connected to the first busbar, and a load connected to the second busbar.

In some examples, the first busbar comprises a first combined busbar and heatsink device, and the second busbar comprises a second combined busbar and heatsink device.

In some examples, the electronic device includes a first fluid thermally coupled to the first combined busbar and heatsink device, and a second fluid thermally coupled to the second combined busbar and heatsink device.

One aspect provides an electronic device including a first die and a second die mounted between a first substrate and a second substrate. The first die includes a first transistor mounted in a first orientation, the first transistor including a first transistor source at a first side of the first die, a first transistor gate at the first side of the first die, and a first transistor drain at a second side of the first die. The second die includes a second transistor mounted in a second orientation inverted relative to the first orientation, the second transistor including a second transistor source at a first side of the second die, a second transistor gate at the first side of the second die, and a second transistor drain at a second side of the second die. The first substrate includes (a) a first substrate source contact, a first substrate gate contact, and a first substrate drain contact on a first side of the first substrate, the first substrate source contact connected to the first transistor source, the first substrate gate contact connected to the first transistor gate, and the first substrate drain contact connected to the second transistor drain, and (b) a first substrate first terminal contact and a first substrate second terminal contact on a second side of the first substrate opposite the first side of the first substrate, the first substrate first terminal contact conductively connected to the first substrate source contact, and the first substrate second terminal contact conductively connected to the first substrate drain contact. The second substrate includes (a) a second substrate source contact, a second substrate gate contact, and a second substrate drain contact on a first side of the second substrate, the second substrate source contact connected to the second transistor source, the second substrate gate contact connected to the second transistor gate, and the second substrate drain contact connected to the first transistor drain, and (b) a second substrate terminal contact on a second side of the second substrate opposite the first side of the second substrate, the second substrate terminal contact conductively connected to the second substrate source contact and the second substrate drain contact.

In some examples, the first substrate comprises a first printed circuit board, and the second substrate comprises a second printed circuit board.

In some examples, the electronic device comprises an inverter.

In some examples, the electronic device includes a gate driver mounted on the first side of the first substrate and connected to the first substrate gate contact.

In some examples, a first busbar electrically and thermally connected to the first substrate first terminal contact, a second busbar electrically and thermally connected to the first substrate second terminal contact, and a third busbar electrically and thermally connected to the second substrate terminal contact.

In some examples, the electronic device includes a power source connected to one of the first busbar and the second busbar, and a load connected to the third busbar.

In some examples, the first busbar comprises a first combined busbar and heatsink device, and the second busbar comprises a second combined busbar and heatsink device.

One aspect provides an electronic device including a die arranged between a first substrate and a second substrate. The first substrate includes a first integrated conductive structure extending through a thickness of the first substrate, the first integrated conductive structure connecting a first substrate die contact on a first side of the first substrate to a first substrate terminal contact on a second side of the first substrate. The second substrate includes a second integrated conductive structure extending through a thickness of the second substrate, the second integrated conductive structure connecting a second substrate die contact on a first side of the second substrate to a second substrate terminal contact on a second side of the second substrate.

The die includes a first side electrically and thermally coupled to the first substrate die contact on the first side of the first substrate, and a second side electrically and thermally coupled to the second substrate die contact on the first side of the second substrate.

In some examples, the first substrate, the die, and the second substrate collectively define a conductive path allowing a communication of current from the first substrate terminal contact to the second substrate terminal contact through the first substrate, the die, and the second substrate, during at least one operational mode of the die.

In some examples, the first substrate comprises a first printed circuit board, and the second substrate comprises a second printed circuit board.

In some examples, the first integrated conductive structure extending through the thickness of the first substrate comprises a metal inlay (a) connected to the first substrate die contact on the first side of the first substrate by a set of first vias and (b) connected to the first terminal contact on the second side of the first substrate by a set of second vias.

### BRIEF DESCRIPTION OF THE DRAWINGS

Example aspects of the present disclosure are described below in conjunction with the figures, in which:

FIG. 1 is a cross-sectional side view of an example electronic device including a die mounted between a first substrate and a second substrate;

FIG. 2 is a cross-sectional side view of an example electronic device including a vertical MOSFET die mounted between a first substrate and a second substrate;

FIG. 3 is a cross-sectional side view of an example power module including a pair of dies mounted between a first substrate and a second substrate;

FIG. 4 is a cross-sectional side view of an example single-phase inverter including the example power module shown in FIG. 3;

FIGS. 5A-5D illustrate various views of an example switching module including a first switch (including five first switch dies) and a second switch (including five second switch dies) arranged between a first substrate and a second substrate; and

FIGS. 6A and 6B various views of an example three-phase inverter module according to one example.

It should be understood the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

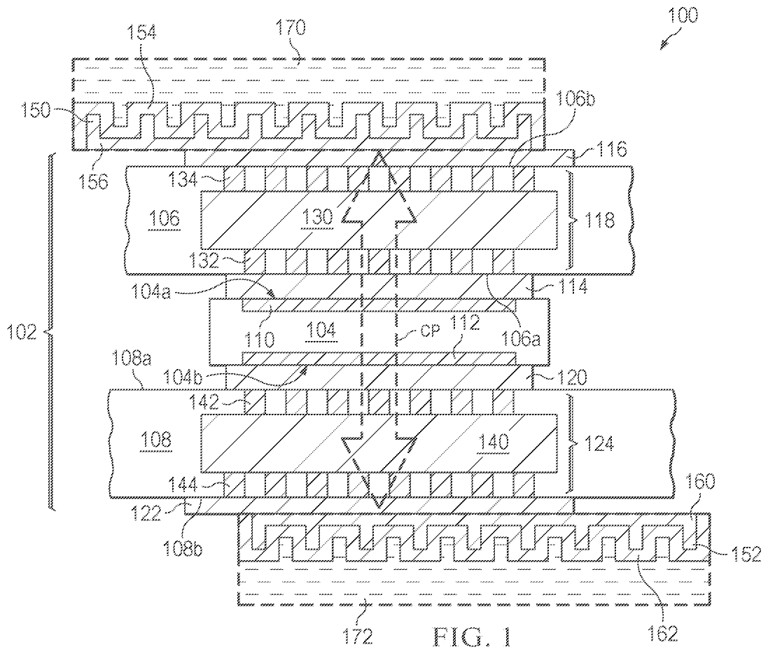

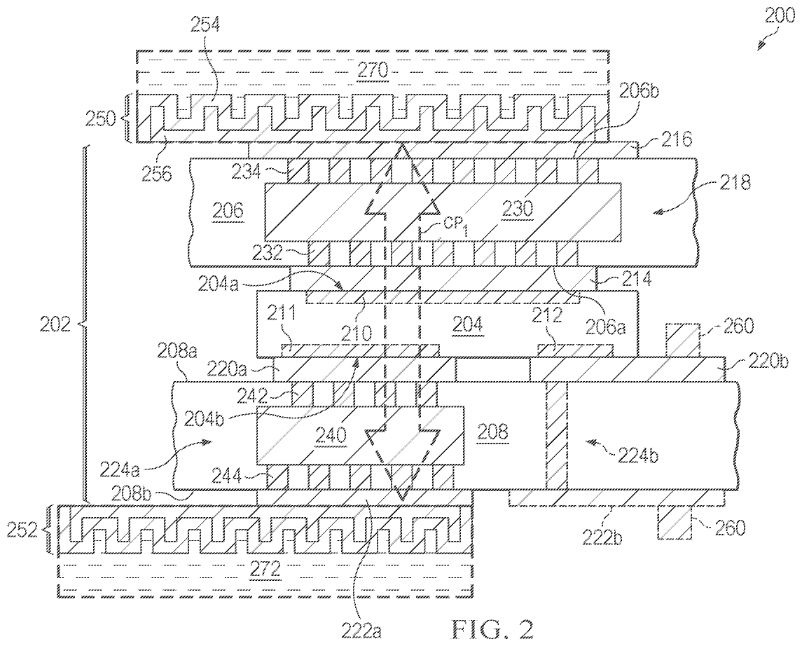

FIG. 1 is a cross-sectional side view of an example electronic device 100 including a power module 102. The power module 102 includes at least one die 104 mounted between a first substrate 106 and a second substrate 108. The illustrated example shows one die 104 mounted between the first substrate 106 and second substrate 108; however, in some examples multiple dies 104 may be mounted between the first substrate 106 and second substrate 108 (e.g., the examples shown in FIGS. 2, 3, 4, 5A-5C, and 6A-6C).

The die 104 may comprise an IC die (chip) or other electronic device including a first die element 110 on a first side 104a of the die 104 and a second die element 112 on a second side 104b of the die 104 opposite the first side 104a. For example, the die 104 may comprise an insulated-gate bipolar transistor (IGBT), a thyristor, a vertical MOSFET (e.g., a power MOSFET) formed from silicon, silicone carbide, gallium nitride, or other suitable material(s), or other type of electronic device. The first die element 110 and second die element 112 may respectively comprise any electronic component of the die 104, or a terminal, bond pad, or other conductive contact on the respective first side 104a or second side 104b of the die 104. In some examples, e.g., as discussed below, the first die element 110 and second die element 112 may respectively comprise a source (or source contact), a drain (or drain contact), or gate (or gate contact) of a MOSFET die.

The first substrate 106 may comprise a first PCB or other substrate including and/or carrying respective circuitry or other electronics. In some examples, the first substrate 106 may be constructed from a number of laminate materials, for example polytetrafluoroethylene (PTFE), epoxy fiberglass (FR-4), bismaleimide triazine epoxy (BT-Epoxy), polyimide, or polyetheretherketone (PEEK). The first substrate 106 may include a first substrate die contact 114 on a first side 106a of the first substrate 106 facing the die 104, and a first substrate terminal contact 116 on a second side 106b of the first substrate 106 opposite the first side 106a of the first substrate 106 and facing away from the die 104. The first substrate terminal contact 116 may be electrically and thermally connected to the first substrate die contact 114 by a first substrate integrated conductive structure 118, and the first substrate die contact 114 may be electrically and thermally connected to the first die element 110, and thereby electrically and thermally connect the first substrate terminal contact 116 with the first die element 110. The first substrate terminal contact 116 may comprise a pad, a trace, or any other conductive structure.

The second substrate 108 may comprise a second PCB or other substrate including and/or carrying respective circuitry or other electronics. Like the first substrate 106, in some examples, the second substrate 108 may be constructed from a number of laminate materials, for example PTFE, epoxy fiberglass (FR-4), BT-Epoxy, polyimide, or PEEK. The second substrate 108 may include a second substrate die contact 120 on a first side 108a of the second substrate 108 facing the die 104, and a second substrate terminal contact 122 on a second side 108b of the second substrate 108 opposite the first side 108a of the second substrate 108 and facing away from the die 104. The second substrate terminal contact 122 may be electrically and thermally connected to the second substrate die contact 120 by a second substrate integrated conductive structure 124, and the second substrate die contact 120 may be electrically and thermally connected to the second die element 112, and thereby electrically and thermally connect the second substrate terminal contact 122 with the second die element 112. The second substrate terminal contact 122 may comprise a pad, a trace, or any other conductive structure.

The first substrate integrated conductive structure 118 and the second substrate integrated conductive structure 124 may respectively include any one or more conductive elements. In some examples, the first substrate 106 and second substrate 108 may be constructed as respective multi-layer substrates, wherein the first substrate integrated conductive structure 118 and the second substrate integrated conductive structure 124 include respective conductive elements formed in the respective multiple layers of the first substrate 106 and second substrate 108.

As one non-limiting example, the first substrate integrated conductive structure 118 may comprise a multi-layer structure including include a metal inlay 130 that is (a) connected to the first substrate die contact 114 by a set of first vias 132 and (b) connected to the first substrate terminal contact 116 by a set of second vias 134. Similarly, the second substrate integrated conductive structure 124 may comprise a multi-layer structure including a metal inlay 140 that is (a) connected to the second substrate die contact 120 by a set of first vias 142 and (b) connected to the second substrate terminal contact 122 by a set of second vias 144. In some examples, metal inlays 130 and 140 may respectively comprise a copper coin, block, or other metal element integrally formed in the respective first substrate 106 and second substrate 108.

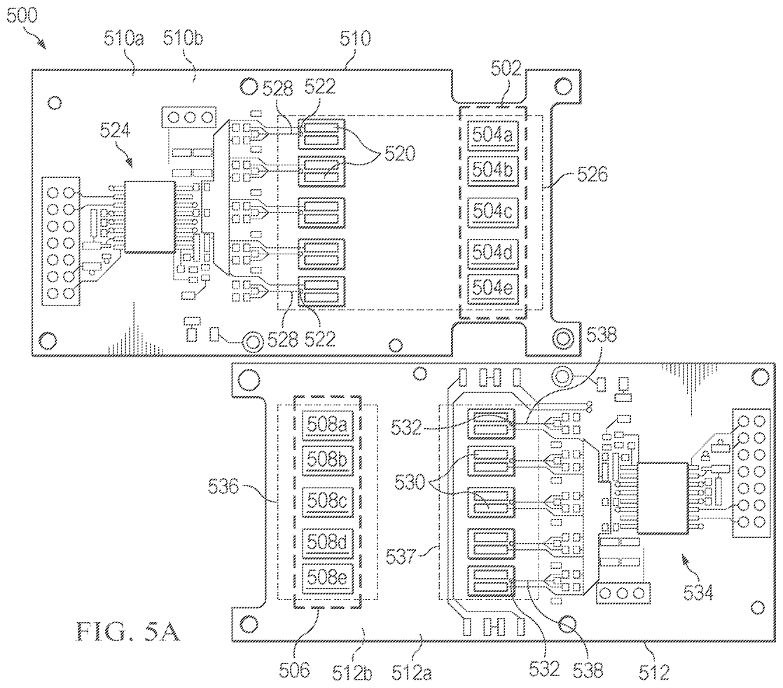

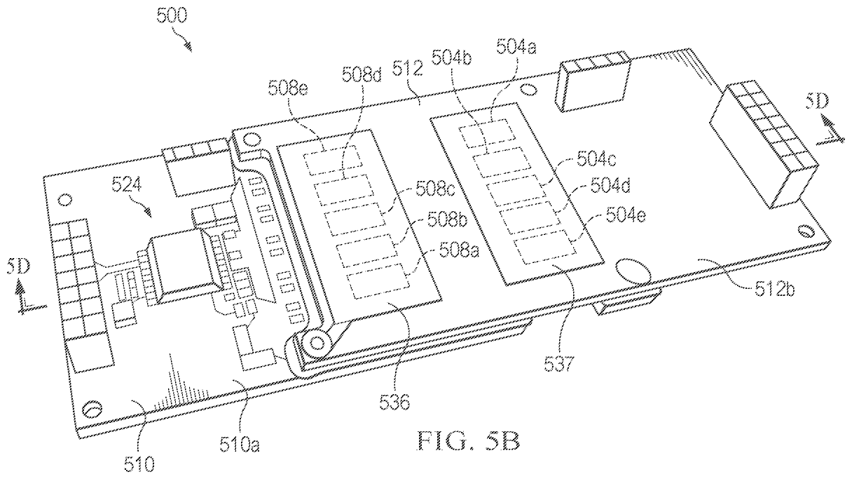

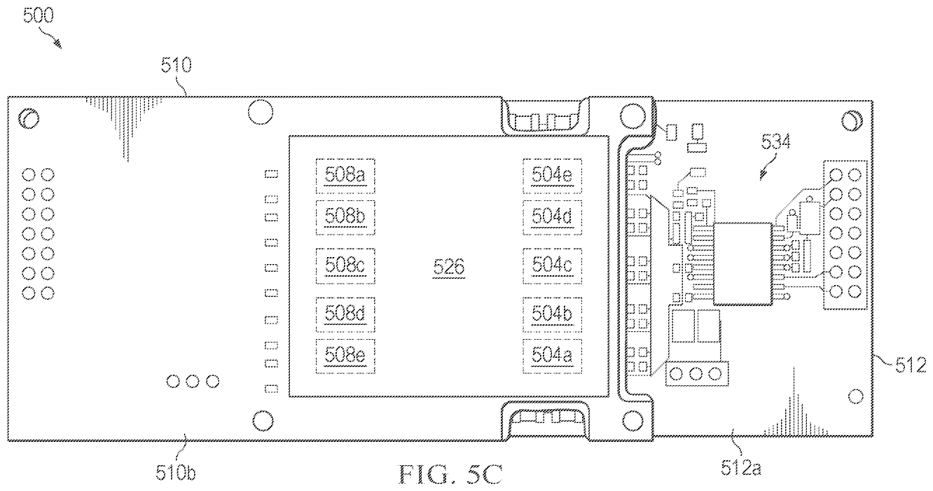

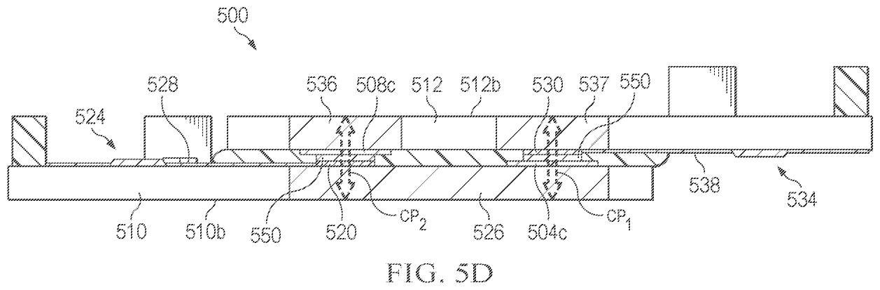

In other examples (e.g., as shown in FIG. 5D discussed below), the first substrate integrated conductive structure 118 and/or second substrate integrated conductive structure 124 may comprise a single unitary conductive element, e.g., a copper block.

In some examples, the first substrate 106, the die 104, and the second substrate 108 collectively define a conductive path CP allowing a communication of current (e.g., electrical signals) from the first substrate terminal contact 116 to the second substrate terminal contact 122 (or vice versa) through the first substrate 106, the die 104, and the second substrate 108, at least in some operational states of the die 104, during at least one operational mode of the die 104. For example, in an example in which the die 104 comprises a transistor (e.g., MOSFET), the conductive path CP may allow a communication of current from the first substrate terminal contact 116 to the second substrate terminal contact 122 (or vice versa) in an “ON” state of the transistor, but not in an “OFF” state of the transistor.

In some examples, the electronic device 100 may optionally include respective elements or devices mounted or otherwise coupled to the power module 102, e.g., at the first substrate terminal contact 116 and/or the second substrate terminal contact 122. For example, the electronic device 100 may optionally include a first busbar 150 electrically and thermally connected to the first substrate terminal contact 116, and a second busbar 152 electrically and thermally connected to the second substrate terminal contact 122. As used herein, a busbar refers to a rigid metal bar or similar structure to carry an electrical current.

In some examples, the first busbar 150 may be a first combined busbar and heatsink device 150 to both (a) transmit electrical current to or from the die 104 (through the first substrate 106) and (b) transmit heat away from the die 104 (through the first substrate 106), and the second busbar 152 may be a second combined busbar and heatsink device 152 to both (a) transmit electrical current to or from the die 104 (through the second substrate 108) and (b) transmit heat away from the die 104 (through the first substrate 106). For example, the first combined busbar and heatsink device 150 may comprise a busbar 154 including a dielectric coating 156, and the second combined busbar and heatsink device 152 may comprise a busbar 160 including a dielectric coating 162, e.g., as disclosed in pending U.S. patent application Ser. No. 17/976,943 (“the '943 Application”), the contents of which application are hereby incorporated by reference.

In some examples, the respective busbars 154 and 160 may comprise copper, aluminum, silver, gold, an alloy of copper, an alloy of aluminum, an alloy of silver, or an alloy of gold, and the respective dielectric coatings 156 and 162 may comprise a polymer, a ceramic, an epoxy, polyphenylene sulfide (PPS), liquid crystal polymer (LCP), polytetrafluoroethylene (PTFE), parylene, polyether ether ketone (PEEK), or a composition including PEEK and parylene.

In some examples, the electronic device 100 may also optionally include a first fluid 170 thermally coupled to the first combined busbar and heatsink device 150, and a second fluid 172 thermally coupled to the second combined busbar and heatsink device 152, e.g., as disclosed in the '943 Application.

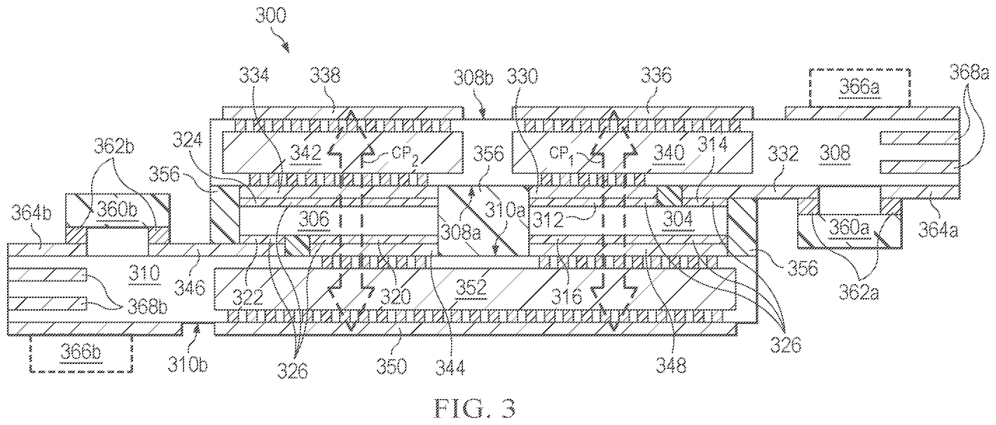

FIG. 2 is a cross-sectional side view of an example electronic device 200 including a power module 202 including a MOSFET die 204 mounted between a first substrate 206 and a second substrate 208. The illustrated example shows one MOSFET die 204 mounted between the first substrate 206 and the second substrate 208; however, in some examples multiple MOSFET dies 204 may be mounted between the first substrate 206 and the second substrate 208 (e.g., the examples shown in FIGS. 3, 4, 5A-5C, and 6A-6C).

In this example, the MOSFET die 204 includes a drain (or drain contact) 210 on a first side 204a of the MOSFET die 204, and a source (or source contact) 211 and a gate (or gate contact) 212 on a second side 204b of the MOSFET die 204 opposite the first side 204a.

The first substrate 206 may comprise a first PCB or other substrate including and/or carrying respective circuitry or other electronics. The first substrate 206 may include a first substrate drain contact 214 on a first side 206a of the first substrate 206 facing the MOSFET die 204, and a drain terminal contact 216 on a second side 206b of the first substrate 206 opposite the first side 206a of the first substrate 206 and facing away from the MOSFET die 204. The drain terminal contact 216 may be electrically and thermally connected to the first substrate drain contact 214 by an integrated drain contact structure 218, and the first substrate drain contact 214 may be electrically and thermally connected to the drain 210, and thereby electrically and thermally connect the drain terminal contact 216 with the drain 210.

The second substrate 208 may comprise a second PCB or other substrate including and/or carrying respective circuitry or other electronics. The second substrate 208 may include a second substrate source contact 220a and a second substrate gate contact 220b on a first side 208a of the second substrate 208 facing the MOSFET die 204, and a source terminal contact 222a on a second side 208b of the second substrate 208 opposite the first side 208a of the second substrate 208 and facing away from the MOSFET die 204. The source terminal contact 222a may be electrically and thermally connected to the second substrate source contact 220a by an integrated source contact structure 224a, and the second substrate source contact 220a may be electrically and thermally connected to the source 211, and thereby electrically and thermally connect the source terminal contact 222a with the source 211.

The integrated drain contact structure 218 and integrated source contact structure 224a may respectively include any one or more conductive elements. As one non-limiting example, the integrated drain contact structure 218 may comprise a multi-layer structure including a metal inlay 230 that is (a) connected to the first substrate drain contact 214 by a set of first vias 232 and (b) connected to the drain terminal contact 216 by a set of second vias 234. Similarly, the integrated source contact structure 224a may comprise a multi-layer structure including a metal inlay 240a that is (a) connected to the second substrate source contact 220a by a set of first vias 242a and (b) connected to the source terminal contact 222a by a set of second vias 244a.

In some examples, the first substrate 206, the MOSFET die 204, and the second substrate 208 collectively define a first conductive path CP₁ allowing (a) a communication of current (e.g., electrical signals) from the drain terminal contact 216 to the source terminal contact 222a (or vice versa) through the first substrate 206, the MOSFET die 204, and the second substrate 208 during at least one operational mode of the die 204, e.g., at least in an “ON” state of the die 204, and (b) heat transfer away from the die 204, e.g., to the drain terminal contact 216 and source terminal contact 222a.

In some examples, the electronic device 200 may optionally include respective conductive elements coupled to the drain terminal contact 216 and source terminal contact 222a. For example, the electronic device 200 may optionally include a first busbar 250 electrically and thermally connected to the drain terminal contact 216, and a second busbar 252 electrically and thermally connected to the source terminal contact 222a, e.g., as discussed above with reference to busbars 150 and 152 shown in FIG. 1.

In some examples, the first busbar 250 and second busbar 252 may respectively comprise a combined busbar and heatsink device, to both (a) transmit electrical current to or from the MOSFET die 204 and (b) transmit heat away from the MOSFET die 204. For example, the first busbar 250 may be a first combined busbar and heatsink device 250, and the second busbar 252 may be a second combined busbar and heatsink device 252. The first combined busbar and heatsink device 250 and second combined busbar and heatsink device 252 may respectively comprise a busbar including a dielectric coating, e.g., as disclosed in the '943 Application. In some examples, the electronic device 200 may also optionally include a first fluid 270 thermally coupled to the first combined busbar and heatsink device 250 and a second fluid 27a thermally coupled to the combined busbar and heatsink device 252, e.g., as disclosed in the '943 Application. The first fluid 270 and second fluid 272 may comprise the same fluid or different fluids.

In some examples, the gate 212 may be connected to gate driver circuitry 260 mounted on the first side 208a of the second substrate 208 (e.g., via the second substrate gate contact 220b) or mounted on the second side 208b of the second substrate 208 (e.g., via an optional integrated gate contact structure 224b formed in the second substrate 208 and an optional second substrate gate contact 222b formed on the second side 208b of the second substrate 208). Alternatively, the gate 212 may be connected to gate driver connector (mounted on the first side 208a or second side 208b of the second substrate 208) allowing connection of external gate driver circuitry (e.g., provided separately from the structure of the power module 202) to the gate 212.

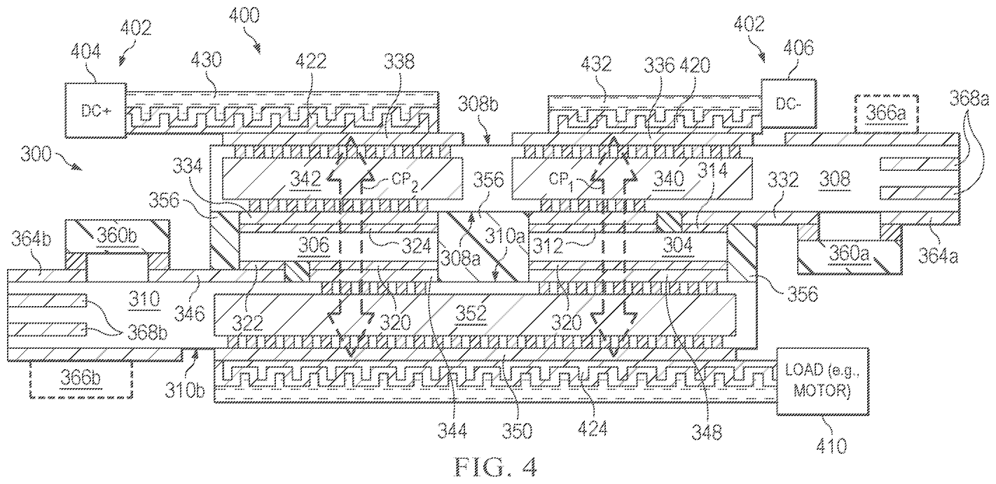

FIG. 3 is a cross-sectional side view of an example power module 300 including a first die 304 and a second die 306 mounted between a first substrate 308 and a second substrate 310. The illustrated example shows two dies (first die 304 and second die 306); however, the power module 300 may include any number of dies; for example, the power module 300 may comprise a switch device including five dies, e.g., as discussed below with reference to the example switch device shown in FIGS. 4, 5A-5C, and 6A-6C).

In the example shown in FIG. 3, the first die 304 comprises a first transistor (e.g., a first MOSFET) mounted in a first orientation (in this example, a “face-up” orientation), and the second die 306 comprises a second transistor (e.g., a second MOSFET) mounted in a second orientation (in this example, a “face-down” orientation) inverted relative to the first orientation (face-up orientation) of the first die 304. According to the face-up orientation of the first die 304, the first transistor includes a first transistor source 312 and a first transistor gate 314 at a first side of the first die 304, and a first transistor drain 316 at a second side of the first die 304. In the example orientation shown in FIG. 3, the first side of the first die 304 faces upwardly, and the second side of the first die 304 faces downwardly, however this is not meant to be limiting in any way.

Further, according to the face-down orientation of the second die 306, the second transistor includes a second transistor source 320 and a second transistor gate 322 at a first side of the second die 306, and a second transistor drain 324 at a second side of the second die 306. In the example orientation shown in FIG. 3, the first side of the second die 306 faces downwardly, and the second side of the second die 306 faces upwardly.

The first substrate 308 may comprise a first PCB or other substrate including and/or carrying respective circuitry or other electronics. The first substrate 308 may be formed as a multi-layer structure, e.g., including conductive routing structures formed therein. The first substrate 308 may include a first substrate source contact 330, a first substrate gate contact 332, and a first substrate drain contact 334 on a first side 308a of the first substrate 308 (facing the first and second dies 304, 306); and a first substrate first terminal contact 336 and a first substrate second terminal contact 338 on a second side 308b of the first substrate 308 (facing away from the first and second dies 304, 306). The first substrate source contact 330 is electrically and thermally connected to the first transistor source 312 (e.g., by a respective solder connection 326), the first substrate gate contact 332 is electrically and thermally connected to the first transistor gate 314 (e.g., by a respective solder connection 326), and the first substrate drain contact 334 is electrically and thermally connected to the second transistor drain 324 (e.g., by a respective solder connection 326).

The first substrate first terminal contact 336 is electrically and thermally connected to the first substrate source contact 330 by an integrated contact structure 340, and the first substrate second terminal contact 338 is electrically and thermally connected to the first substrate drain contact 334 by an integrated contact structure 342. The integrated contact structures 340 and 342 may comprise respective multi-layer conductive structures, e.g., as described above regarding example integrated conductive structures 118, 124, 218, 224a, and 224b.

The second substrate 310 may comprise a second PCB or other substrate including and/or carrying respective circuitry or other electronics. The second substrate 310 may be formed as a multi-layer structure, e.g., including conductive routing structures formed therein. The second substrate 310 may include a second substrate source contact 344, a second substrate gate contact 346, and a second substrate drain contact 348 on a first side 310a of the second substrate 310 (facing the first and second dies 304, 306); and a second substrate terminal contact 350 on a second side 310b of the second substrate 310 (facing away from the first and second dies 304, 306). The second substrate source contact 344 is electrically and thermally connected to the second transistor source 320 (e.g., by a respective solder connection 326), the second substrate gate contact 346 is electrically and thermally connected to the second transistor gate 322 (e.g., by a respective solder connection 326), and the second substrate drain contact 348 is electrically and thermally connected to the first transistor drain 316 (e.g., by a respective solder connection 326). The second substrate terminal contact 350 is electrically and thermally connected to both (a) the second substrate source contact 344 and (b) the second substrate drain contact 348 by an integrated contact structure 352, which may comprise a multi-layer conductive structure, e.g., as described above regarding example integrated conductive structures 118, 124, 218, 224a, and 224b.

The first substrate 308, the first die 304, and the second substrate 310 collectively define a first conductive path CP₁ allowing (a) a communication of current (e.g., electrical signals) between the first substrate first terminal contact 336 and the second substrate terminal contact 350 through the first substrate 308, the first die 304, and the second substrate 310, at least in an “ON” state of the first die 304, and (b) heat transfer away from the first die 304, e.g., to the first substrate first terminal contact 336 and the second substrate terminal contact 350.

Similarly, the first substrate 308, the second die 364, and the second substrate 310 collectively define a second conductive path CP₂ allowing (a) a communication of current between the first substrate second terminal contact 338 and the second substrate terminal contact 350 through the first substrate 308, the second die 364, and the second substrate 310, at least in an “ON” state of the second die 364, and (b) heat transfer away from the second die 364, e.g., to the first substrate second terminal contact 338 and the second substrate terminal contact 350.

A mold compound or underfill 356 may be arranged between the first substrate 308 and second substrate 310, e.g., to encapsulate the first die 304 and second die 306. In some examples, the mold compound or underfill 356 may comprise an epoxy polymer, an epoxy polymer with filler (e.g., in the form of underfills, fills, or globs, without limitation), or a silicone gel, for example.

The power module 300 may include additional circuitry elements associated with the operation of the first and second dies 304, 306. For example, as shown in FIG. 3, power module 300 may include gate drivers, gate driver control circuitry, and additional circuitry formed in, formed on, or mounted on the first substrate 308 and second substrate 310. As shown, power module 300 may include (a) first gate driver circuitry 360a mounted on the first side 308a of the first substrate 308 and connected to the first transistor gate 314 by the first substrate gate contact 332 formed on the first substrate 308, and (b) second gate driver circuitry 360b mounted on the first side 310a of the second substrate 308 and connected to the second transistor gate 322 by the first substrate gate contact 346 formed on the second substrate 310. In one example, the first gate driver circuitry 360a may be soldered to the first substrate gate contact 332 and to further conductive trace(s) 364a by respective first solder connections 362a, and the second gate driver circuitry 360b may be soldered to the second substrate gate contact 346 and to further conductive trace(s) 364b by respective second solder connections 362b.

In some examples, the power module 300 may further include gate driver control circuitry to control respective first gate driver circuitry 360a and second gate driver circuitry 360b. For example, as shown in FIG. 3, the power module 300 may include (a) first gate driver control circuitry 366a mounted on the first substrate 308 and connected to the first gate driver circuitry 360a (e.g., by traces formed on the first substrate 308 and/or internal conductive structures extending through the first substrate 308), and (b) second gate driver control circuitry 366b mounted on the second substrate 310 and connected to the second gate driver circuitry 360b (e.g., by traces formed on the second substrate 310 and/or internal conductive structures extending through the first substrate 310). Alternatively, the power module 300 may include PCB connectors or other connections to connect to separate gate driver control circuitry (i.e., not mounted on first substrate 308 or second substrate 310) to control respective first gate driver circuitry 360a and second gate driver circuitry 360b. For example, FIG. 3 shows an example first connector structure 368a to connect to respective gate driver control circuitry to control the first gate driver circuitry 360a, and an example second connector structure 368b to connect to respective gate driver control circuitry to control the second gate driver circuitry 360b.

In some examples, electronic devices as disclosed herein, e.g., one or more instance of the power module 300 discussed above, can be arranged in various circuitry topologies, for example a half bridge topology, an H-Bridge topology, a single-phase inverter topology, a three-phase inverter topology, a neutral point clamped (NPC) topology, a mixed voltage NPC (MNPC), or an active NPC (ANPC) topology, without limitation.

FIG. 4 is a cross-sectional side view of an example single phase inverter module 400 (also referred to as inverter 400 for convenience) including the example power module 300 shown in FIG. 3 and discussed above. As discussed above, the example power module 300 includes a pair of MOSFET dies (first die 304 and second die 306) arranged between the first substrate 308 and second substrate 310, wherein the first die 304 is arranged in a face-up orientation and the second die 306 is arranged in a face-down orientation (i.e., inverted relative to the first die 304).

The inverter 400 includes a DC power supply 402 connected to the first transistor source 312 and the second transistor drain 324, and a load 410 (e.g., a motor) connected to the first transistor drain 316 and the second transistor source 320, i.e. to the second substrate terminal contact 350. In particular, the DC power supply 402 may include (a) a DC+ terminal connected to the first substrate second terminal contact 338 (which is connected to the second transistor drain 324 via the integrated contact structure 342 and first substrate source contact 334) by a first combined busbar/heatsink 422, and (b) a DC− terminal connected to the first substrate first terminal contact 336 (which is connected to the second transistor source 312 via the integrated contact structure 340 and first substrate source contact 330) by a second combined busbar/heatsink 420. The load 410 (e.g., a motor) may be connected to the second substrate terminal contact 350 (which is connected to (a) the first transistor drain 316 via the integrated contact structure 352 and the second substrate drain contact 348 and (b) the second transistor source 320 via the integrated contact structure 352 and the second substrate source contact 344) by a third combined busbar/heatsink 424.

In some examples, the first combined busbar/heatsink 422, second combined busbar/heatsink 420, and third combined busbar/heatsink 424 may respectively comprise a busbar including a dielectric coating, e.g., as disclosed in the '943 Application. As shown in FIG. 4, the inverter 400 may include a first fluid 430 thermally coupled to the first combined busbar/heatsink 422, a second fluid 432 thermally coupled to the second combined busbar/heatsink 420, and a third fluid 434 thermally coupled to the third combined busbar/heatsink 424, e.g., as disclosed in the '943 Application.

FIGS. 5A-5D illustrate an example switching module 500 including a first switch 502 including five first switch dies 504a-504e and a second switch 506 including five second switch dies 508a-508e, wherein the first switch dies 504a-504e and second switch dies 508a-508e are arranged between a first substrate 510 and a second substrate 512.

FIG. 5A shows the first substrate 510 and second substrate 512 in a partially assembled state, prior to mounting the first substrate 510 and second substrate 512 to each other. In particular, FIG. 5A shows the first substrate 510 and second substrate 512 in a “face-up” orientation, wherein a first side 510a of the first substrate 510 and a first side 512a of the second substrate 512 are visible. As shown, the first switch dies 504a-504e (connected in parallel) are mounted on the first side 510a of the first substrate 510, along with source contacts 520 and gate contacts 522 to contact the second switch dies 508a-508e in the fully assembled state of the switching module 500 (shown in FIGS. 5B-5D), and first gate driver circuitry 524 connected to the gate contacts 522. First gate driver circuitry 524 may include, for example, an ASIC chip, capacitors, gate resistors, diodes, and other circuitry elements for driving respective gates of second switch dies 508a-508e via respective gate contacts 522 (in the fully assembled state of the switching module 500 shown in FIGS. 5B-5D).

The first switch dies 504a-504e may be mounted on respective drain contacts (not shown) formed on the first substrate 510. In the illustrated example, the first switch dies 504a-504e and source contacts 520 are conductively connected to an AC output terminal pad 526 integrated in the first substrate 510. The AC output terminal pad 526 may be exposed on a second side 510b of the first substrate 510, as shown in FIG. 5C.

Similarly, the second switch dies 508a-508e (connected in parallel) are mounted on the first side 512a of the second substrate 512, along with source contacts 530 and gate contacts 532 to contact the first switch dies 504a-504e in the fully assembled state of the switching module 500, and second gate driver circuitry 534 connected to the gate contacts 532. Second gate driver circuitry 534 may include, for example, an ASIC chip, capacitors, gate resistors, diodes, and other circuitry elements for driving respective gates of first switch dies 504a-504e via respective gate contacts 532 (in the fully assembled state of the switching module 500 shown in FIGS. 5B-5D).

The second switch dies 508a-508e may be mounted on respective drain contacts (not shown) formed on the second substrate 512. In the illustrated example, the second switch dies 508a-508e are conductively connected to DC+ terminal pad 536 integrated in the second substrate 512, and source contacts 530 are conductively connected to a DC− terminal pad 537 integrated in the second substrate 512. The DC+ terminal pad 536 and DC− terminal pad 537 may be exposed on a second side 512b of the second substrate 512, as shown in FIG. 5B

In some examples, respective gate contacts 522 are connected to first gate driver circuitry 524 by respective conductive traces 528 formed on the first substrate 510, and respective gate contacts 532 are connected to second gate driver circuitry 534 by respective conductive traces 538 formed on the second substrate 512, thereby eliminating the need for wire bonds or off-module interconnects required in certain conventional devices.

FIG. 5B shows a top view of the switching module 500 in an assembled state, wherein the first side 510a of the first substrate 510 is mounted against the first side 512a of the second substrate 512. In particular, FIG. 5B shows the first substrate 510 in the face-up orientation, and the second substrate 512 in a face-down orientation (i.e., flipped over from the face-up orientation shown in FIG. 5A) showing a second side 512b of the second substrate 512. In the assembled state, the respective first switch dies 504a-504e mounted on the first substrate 510 are connected (e.g., by respective solder bonds) to source contacts 530 and gate contacts 532 provided on the second substate 512, and respective second switch dies 508a-508e mounted on the second substrate 512 are connected (e.g., by respective solder bonds) to source contacts 520 and gate contacts 522 provided on the first substate 510.

As shown in FIG. 5B, the DC+ terminal pad 536 and DC− terminal pad 537 are exposed on the second side 512b of the second substrate 512. The DC+ terminal pad 540 is electrically and thermally connected to the first switch dies 504a-504e, and the DC− terminal pad 542 is electrically and thermally connected to the second switch dies 508a-508e.

FIG. 5C shows a bottom view of the switching module 500 in the assembled state, showing the second side 510b of the first substrate 510. As shown, the AC output terminal pad 526 is exposed on the second side 510b of the first substrate 510. The AC output terminal pad 526 is electrically and thermally connected to the first switch dies 504a-504e and second switch dies 508a-508e.

FIG. 5D is a cross-sectional side view of the switching module 500 in the assembled state in which respective electronics on the first substrate 510 are mounted to opposing electronics on the second substrate 512. In particular, FIG. 5D shows a cross-section though line 5D-5D shown in FIG. 5B, which cuts through the first switch die 504c of the first switch 502 and second switch die 508c of the second switch 506. As shown, the first switch die 504c is mounted to the AC output terminal pad 526 formed in the first substrate 510, the second switch die 508c is mounted to the DC+ output terminal pad 536 formed in the second substrate 512, and a respective source contact 530 is mounted to the DC− output terminal pad 537 formed in the second substrate 512. The first switch die 504c may be bonded, e.g., by a solder bond 550, to a respective source contact 530 provided on the second substrate 512, and the second switch die 508c may be bonded, e.g., by a solder bond 550, to a respective source contact 520 provided on the first substrate 510.

As shown in FIG. 5D, the AC output terminal pad 526, the first switch die 504c, and the DC− output terminal pad 537 collectively define a first conductive path CP₁ allowing heat transfer away from the first switch die 504c and conduction of current (e.g., electrical signals) to and/or from the first switch die 504c. Further, the AC output terminal pad 526, the second switch die 508c, and the DC+ output terminal pad 536 collectively define a second conductive path CP₂ allowing heat transfer away from the second switch die 508c and conduction of current (e.g., electrical signals) to and/or from the second switch die 508c.

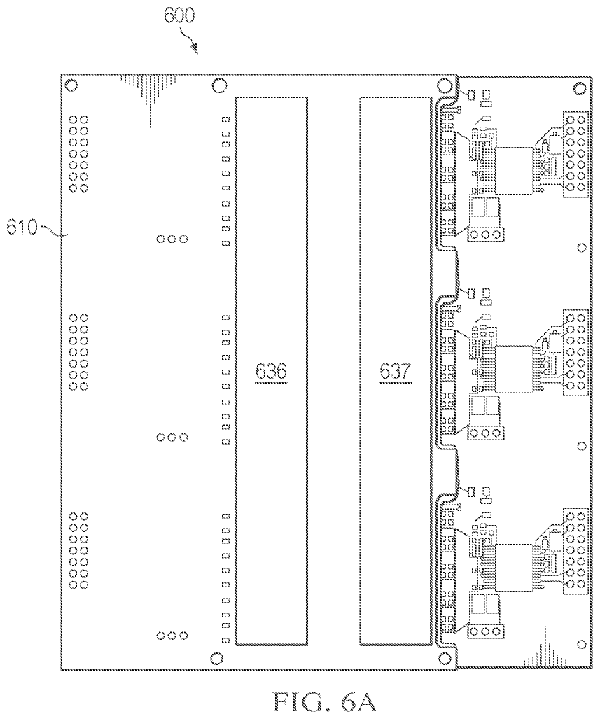

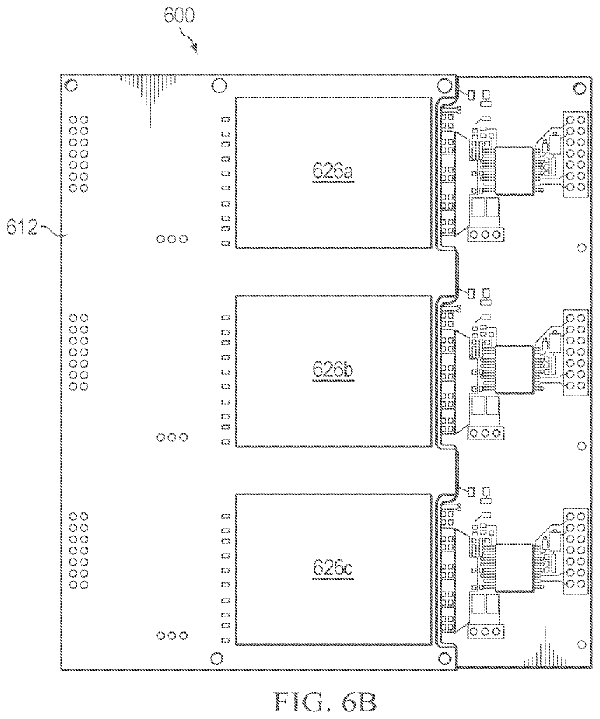

FIGS. 6A and 6B show an example three-phase inverter module 600 according to one example. FIG. 6A shows a first side view (e.g., top view) showing a first substrate 610 including a DC+ power source terminal pad 636 and a DC− power source terminal pad 637. FIG. 6B shows a second side view (e.g., a bottom view), showing a second substrate 612 including three single-phase AC terminal pads 626a, 626b, and 626c (also referred to as P1, P2, and P3 terminals) for connection to a three-phase AC load, e.g., motor (not shown). A respective set of dies (e.g., defining one or more switch) may be connected between the assembled first substrate 610 and second substrate 612, e.g., similar to first switch dies 504a-504e defining first switch 502 and second switch dies 504a-504e defining second switch 506 of the example switching module 500 discussed above.

Although example embodiments have been described above, other variations and embodiments may be made from this disclosure without departing from the spirit and scope of these embodiments.

1. An electronic device, comprising:
a die mounted between a first substrate and a second substrate, the die including:
a first die element at a first side of the die;
a second die element at a second side of the die opposite the first side of the die;
the first substrate including:
a first substrate die contact on a first side of the first substrate, the first substrate die contact electrically and thermally connected to the first die element; and
a first substrate terminal contact on a second side of the first substrate opposite the first side of the first substrate, the first substrate terminal contact electrically and thermally connected to the first substrate die contact;
the second substrate including:
a second substrate die contact on a first side of the second substrate, the second substrate die contact electrically and thermally connected to the second die element; and
a second substrate terminal contact on a second side of the second substrate opposite the first side of the second substrate, the second substrate terminal contact electrically and thermally connected to the second substrate die contact.

2. The electronic device of claim 1, wherein the first substrate, the die, and the second substrate collectively define a conductive path allowing a communication of current from the first substrate terminal contact to the second substrate terminal contact through the first substrate, the die, and the second substrate, during at least one operational mode of the die.

3. The electronic device of claim 1, comprising:
a first substrate integrated conductive structure extending through a thickness of the first substrate to electrically and thermally connect the first substrate die contact with the first substrate terminal contact; and
a second substrate integrated conductive structure extending through a thickness of the second substrate to electrically and thermally connect the second substrate die contact with the second substrate terminal contact.

4. The electronic device of claim 1, wherein the first substrate comprises a first printed circuit board, and the second substrate comprises a second printed circuit board.

5. The electronic device of claim 1, wherein:
the die comprises a vertical transistor;
the first die element comprises a source of the vertical transistor;
the second die element comprises a drain of the vertical transistor;
the first substrate die contact on the first side of the first substrate comprises a source contact; and
the second substrate die contact on the first side of the second substrate comprises a drain contact.

6. The electronic device of claim 5, wherein:
the die comprises a gate terminal of the vertical transistor;
the first substrate comprises a gate contact on the first side of the first substrate; and
the electronic device comprises a gate driver mounted on the first substrate and connected to the gate contact.

7. The electronic device of claim 6, comprising gate driver control circuitry mounted on the first substrate and connected to the gate driver.

8. The electronic device of claim 1, comprising:
a first busbar electrically and thermally connected to the first substrate terminal contact; and
a second busbar electrically and thermally connected to the second substrate terminal contact.

9. The electronic device of claim 8, comprising:
a power supply connected to the first busbar; and
a load connected to the second busbar.

10. The electronic device of claim 8, wherein:
the first busbar comprises a first combined busbar and heatsink device; and
the second busbar comprises a second combined busbar and heatsink device.

11. The electronic device of claim 10, comprising:
a first fluid thermally coupled to the first combined busbar and heatsink device; and
a second fluid thermally coupled to the second combined busbar and heatsink device.

12. An electronic device, comprising:
a first substrate;
a second substrate;
a first die comprising a first transistor mounted in a first orientation, the first transistor including a first transistor source at a first side of the first die, a first transistor gate at the first side of the first die, and a first transistor drain at a second side of the first die; and
a second die comprising a second transistor mounted in a second orientation inverted relative to the first orientation, the second transistor including a second transistor source at a first side of the second die, a second transistor gate at the first side of the second die, and a second transistor drain at a second side of the second die;
the first substrate including:
a first substrate source contact, a first substrate gate contact, and a first substrate drain contact on a first side of the first substrate, the first substrate source contact connected to the first transistor source, the first substrate gate contact connected to the first transistor gate, and the first substrate drain contact connected to the second transistor drain; and
a first substrate first terminal contact and a first substrate second terminal contact on a second side of the first substrate opposite the first side of the first substrate, the first substrate first terminal contact conductively connected to the first substrate source contact, and the first substrate second terminal contact conductively connected to the first substrate drain contact; and
the second substrate including:
a second substrate source contact, a second substrate gate contact, and a second substrate drain contact on a first side of the second substrate, the second substrate source contact connected to the second transistor source, the second substrate gate contact connected to the second transistor gate, and the second substrate drain contact connected to the first transistor drain; and
a second substrate terminal contact on a second side of the second substrate opposite the first side of the second substrate, the second substrate terminal contact conductively connected to the second substrate source contact and the second substrate drain contact.

13. The electronic device of claim 12, wherein the first substrate comprises a first printed circuit board, and the second substrate comprises a second printed circuit board.

14. The electronic device of claim 12, wherein the electronic device comprises an inverter.

15. The electronic device of claim 12, comprising a gate driver mounted on the first side of the first substrate and connected to the first substrate gate contact.

16. The electronic device of claim 12, comprising:
a first busbar electrically and thermally connected to the first substrate first terminal contact;
a second busbar electrically and thermally connected to the first substrate second terminal contact; and
a third busbar electrically and thermally connected to the second substrate terminal contact.

17. The electronic device of claim 16, comprising:
a power source connected to one of the first busbar and the second busbar; and
a load connected to the third busbar.

18. The electronic device of claim 16, wherein:
the first busbar comprises a first combined busbar and heatsink device; and
the second busbar comprises a second combined busbar and heatsink device.

19. An electronic device, comprising:
a first substrate including a first integrated conductive structure extending through a thickness of the first substrate, the first integrated conductive structure connecting a first substrate die contact on a first side of the first substrate to a first substrate terminal contact on a second side of the first substrate;
a second substrate including a second integrated conductive structure extending through a thickness of the second substrate, the second integrated conductive structure connecting a second substrate die contact on a first side of the second substrate to a second substrate terminal contact on a second side of the second substrate; and
a die arranged between the first substrate and the second substrate, the die having (a) a first side electrically and thermally coupled to the first substrate die contact on the first side of the first substrate, and (b) a second side electrically and thermally coupled to the second substrate die contact on the first side of the second substrate.

20. The electronic device of claim 19, wherein the first substrate, the die, and the second substrate collectively define a conductive path allowing a communication of current from the first substrate terminal contact to the second substrate terminal contact through the first substrate, the die, and the second substrate, during at least one operational mode of the die.

21. The electronic device of claim 19, wherein the first substrate comprises a first printed circuit board, and the second substrate comprises a second printed circuit board.

22. The electronic device of claim 19, wherein the first integrated conductive structure extending through the thickness of the first substrate comprises a metal inlay (a) connected to the first substrate die contact on the first side of the first substrate by a set of first vias and (b) connected to the first terminal contact on the second side of the first substrate by a set of second vias.
